(19) United States
(12) Patent Application Publication
(10) Pub. No.: US 2026/0215333 A1
(43) Pub. Date: Jul. 23, 2026

(54) SEMICONDUCTOR MODULE AND MANUFACTURING METHOD FOR THE SAME

(71) Applicant: FUJI ELECTRIC CO., LTD., Kawasaki-shi (JP)

(72) Inventors: Yuichiro HINATA, Matsumoto-city (JP); Naoyuki KANAI, Matsumoto-city (JP)

(73) Assignee: FUJI ELECTRIC CO., LTD., Kawasaki-shi (JP)

(21) Appl. No.: 19/568,157

(22) Filed: Mar. 16, 2026

Related U.S. Application Data
(63) Continuation of application No. PCT/JP2025/003435, filed on Feb. 3, 2025.

(30) Foreign Application Priority Data
Mar. 15, 2024 (JP) 2024-041065

(51) Int. Cl. H10W 76/47; H10W 76/05

(52) U.S. Cl. CPC H10W 76/47; H10W 76/05

(57) ABSTRACT

A semiconductor module includes a case and a sealing resin. The case includes, on an upper surface thereof, a first region and a second region that is thinner than the first region. A first opening and a recess that annularly surrounds the first opening are formed in the second region. The sealing resin fills the case.

### CROSS-REFERENCE TO RELATED APPLICATION(S)

This application is a continuation application of International Application PCT/JP2025/003435 filed on Feb. 3, 2025, which designated the U.S., and claims priority to Japanese Patent Application No. 2024-041065, filed on Mar. 15, 2024, the entire contents of which are incorporated herein by reference.

### BACKGROUND OF THE INVENTION

### 1. Field of the Invention

The embodiments discussed herein relate to a semiconductor module and a manufacturing method for the same.

### 2. Background of the Related Art

There is a semiconductor device in which a hole for injecting a sealing resin or introducing a high-pressure gas is provided in an upper surface of a case (see, for example, Japanese Laid-open Patent Publication No. H06-188335, Japanese Laid-open Patent Publication No. 2003-273260, Japanese Laid-open Patent Publication No. 2005-294792). In addition, there is an electronic control device in which a breathing hole for eliminating a pressure difference between the inside and the outside is provided in an upper surface of a cover that covers a circuit board (see, for example, Japanese Laid-open Patent Publication No. 2012-69647). Further, in order to reduce a space generated when a lead frame is sandwiched between upper and lower dies, there is a technique in which a convex portion is provided in a die at a position corresponding to a hole of the lead frame (for example, see Japanese Laid-open Patent Publication No. H06-304959).

### SUMMARY OF THE INVENTION

According to an aspect of the present disclosure, there is provided a semiconductor module, including: a case including a first region and a second region on an upper surface thereof, the second region being thinner than the first region and having a first opening and a recess, which annularly surrounds the first opening in a plan view of the semiconductor module, formed therein; and a sealing resin filling the case.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view illustrating an appearance of a semiconductor module according to a comparative example;

FIG. 2 is a sectional view of the semiconductor module according to the comparative example, taken along a line II-II of FIG. 1;

FIGS. 3A and 3B are plan views of a printed board and an insulated circuit substrate, respectively;

FIG. 4 illustrates how to perform positioning using positioning members;

FIGS. 5A and 5B illustrate a problem in manufacturing the semiconductor module of the comparative example;

FIG. 6 is a plan view of a semiconductor module according to a first embodiment, before mold clamping;

FIG. 7 is a sectional view of the semiconductor module according to the first embodiment, taken along a line VII-VII of FIG. 6 before mold clamping;

FIGS. 8A and 8B illustrate states of the semiconductor module according to the first embodiment, during the mold clamping;

FIG. 9 illustrates a state in which a sealing resin is injected into the case of the semiconductor module of the first embodiment;

FIG. 10 is a sectional view of the semiconductor module according to the first embodiment;

FIGS. 11A and 11B are a plan view and a sectional view, respectively, of a peripheral portion of the first opening formed in the case of the semiconductor module according to the first embodiment, in a state after mold clamping;

FIGS. 12A and 12B are a plan view and a sectional view, respectively, of a peripheral portion of a first opening formed in a case of a semiconductor module according to a second embodiment, in a state before mold clamping;

FIGS. 13A and 13B are a plan view and a sectional view, respectively, of the peripheral portion of the first opening formed in the case of the semiconductor module according to the second embodiment, in a state after mold clamping;

FIGS. 14A and 14B are a plan view and a sectional view, respectively, of a peripheral portion of a first opening formed in a case of a semiconductor module according to a third embodiment, in a state before mold clamping;

FIGS. 15A and 15B are a plan view and a sectional view, respectively, of the peripheral portion of the first opening formed in the case of the semiconductor module according to the third embodiment, in a state after mold clamping;

FIGS. 16A and 16B are a plan view and a sectional view, respectively, of a peripheral portion of a first opening formed in a case of a semiconductor module according to a fourth embodiment, in a state before mold clamping;

FIGS. 17A and 17B are a plan view and a sectional view, respectively, of the peripheral portion of the first opening formed in the case of the semiconductor module according to the fourth embodiment, in a state after mold clamping;

FIG. 18 illustrates a manufacturing process for a semiconductor module;

FIG. 19 is a sectional view illustrating a state of positioning using positioning members; and

FIG. 20 illustrates a modification of a semiconductor module.

### DETAILED DESCRIPTION OF THE INVENTION

Hereinafter, embodiments of the present disclosure will be described with reference to the drawings.

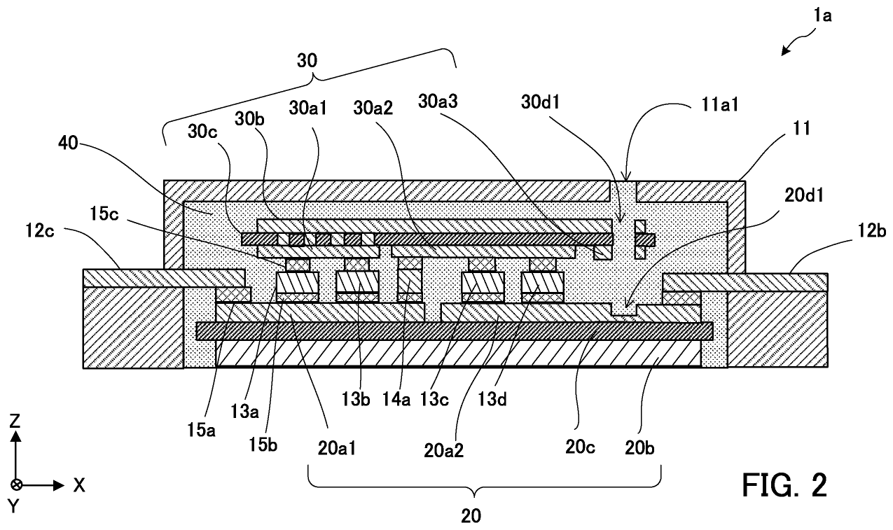

In the following description, the terms “front surface” and “upper surface” refer to an X-Y plane facing upward (+Z direction) in a semiconductor module 1a of FIG. 2 and others. Similarly, the term “up” refers to an upward direction (+Z direction) in the semiconductor module 1a of FIG. 2 and others. The terms “back surface” and “lower surface” refer to an X-Y plane facing downward (−Z direction) in the semiconductor module 1a of FIG. 2 and others. Similarly, the term “down” refers to a downward direction (−Z direction) in the semiconductor module 1a of FIG. 2 and others. The same definition of directions applies to other drawings where appropriate. The terms “front surface”, “upper surface”, “up”, “back surface”, “lower surface”, and “down” are used merely for convenience in describing relative positional relationships, and do not limit the technical concept of the embodiments. For example, the terms “up” and “down” are not necessarily related to the vertical directions to the ground. That is, the “up” and “down” directions are not limited to those related to the direction of gravity.

First, before describing a semiconductor module of a first embodiment, a semiconductor module of a comparative example will be described below.

### Comparative Example

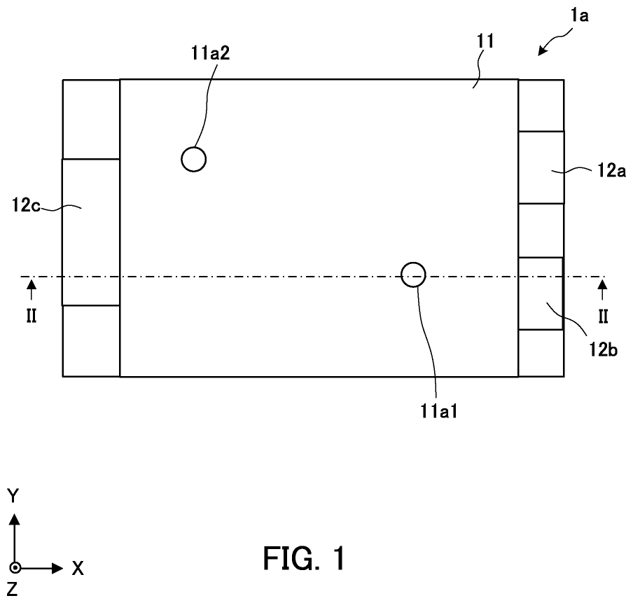

FIG. 1 is a plan view illustrating an appearance of a semiconductor module according to a comparative example.

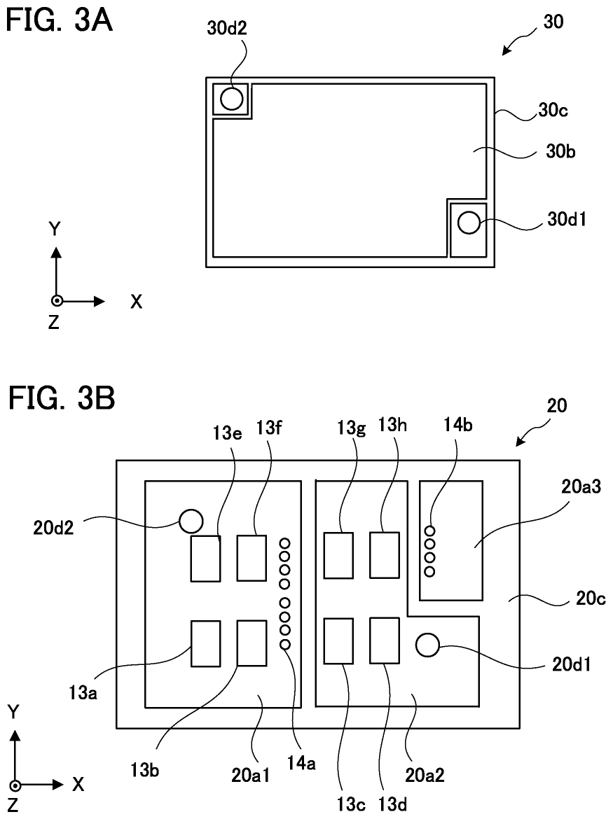

FIG. 2 is a sectional view of the semiconductor module according to the comparative example, taken along a line II-II of FIG. 1. FIGS. 3A and 3B are plan views of a printed board and an insulated circuit substrate, respectively.

A semiconductor module 1 a of the comparative example includes a case 11, semiconductor elements 13a to 13h, an insulated circuit substrate 20, a printed board 30, and a sealing resin 40.

The case 11 has first openings 11a1 and 11a2, which are through holes, in the upper surface thereof. Positioning members are inserted into the first openings 11a1 and 11a2 when the positioning of the case 11 and components (the insulated circuit substrate 20 and the printed board 30) provided inside the case 11 is performed. Since pin-shaped positioning members are inserted, the first opening 11a1 is provided at the same position as a second opening 30d1 formed in the printed board 30 and a third opening 20d1 formed in the insulated circuit substrate 20 in plan view. Similarly, the first opening 11a2 is provided at the same position as a second opening 30d2 formed in the printed board 30 and a third opening 20d2 formed in the insulated circuit substrate 20 in plan view.

The diameters of the first openings 11a1 and 11a2 are determined according to the diameters of the positioning members to be used. If the positioning members are too thin, the positioning members may be easily deformed. On the other hand, if the positioning members are too thick, the opening sizes of the second openings 30d1 and 30d2 provided in the printed board 30 and the third openings 20d1 and 20d2 provided in the insulated circuit substrate 20 need to be large accordingly. Therefore, for example, it is preferable that the diameters of the positioning members be in the range of 1 mm to 2 mm, inclusive, and the diameters of the first openings 11a1 and 11a2 be in the range of 1 mm to 2 mm, inclusive, accordingly.

The shapes of the first openings 11a1 and 11a2 in plan view are not limited to a circular shape as illustrated in FIG. 1. In plan view, the first openings 11a1 and 11a2 may have a shape other than a circular shape, such as a quadrangular shape. The number of first openings is not limited to two. Note, however, that at least two first openings are preferably provided in order to achieve accurate positioning.

Further, the case 11 has terminals 12a to 12c, which each have one end protruding into the case from the inner surface of the case and the other end exposed to the outside of the case 11. The terminals 12a to 12c are formed integrally with the case 11.

The case 11 is formed by injection molding using a thermoplastic resin, for example. Examples of the thermoplastic resin include a polyphenylene sulfide resin, a polybutylene terephthalate resin, a polybutylene succinate resin, a polyamide resin, an acrylonitrile butadiene styrene resin, and a liquid crystal polymer. The case 11 has a thickness needed for the molding. Such a thickness is, for example, in the range of 1 mm to 2 mm, inclusive.

The terminals 12a and 12b are external connection terminals for a main current, to which different potentials are applied. For example, the negative terminal of a direct current power supply is connected to the terminal 12a, and the positive terminal of the direct current power supply is connected to the terminal 12b. The terminal 12c is an output terminal. The terminals 12a to 12c are made of a material having excellent electrical conductivity. Such a material is, for example, aluminum, iron, silver, copper, or an alloy containing at least one of these. The number of terminals may be changed as appropriate depending on the type or others of the semiconductor module 1a. In the case where the semiconductor module 1a is a three-level inverter, a terminal called a neutral terminal (or an intermediate terminal) or the like may be additionally formed integrally with the case 11. Although not illustrated, other terminals such as control terminals that are electrically connected to the control electrodes of the semiconductor elements 13a to 13h may be formed integrally with the case 11. The space between the terminals is filled with the resin of the case 11, so as to maintain the insulation between the terminals.

In this connection, the upper surface of the case 11 may be provided with one or more additional openings (through holes) having an opening area larger than those of the first openings 11a1 and 11a 2 in a region where the first openings 11a1 and 11a 2 are not provided, so as to allow internal components to be visually confirmed during assembly. In addition, the upper surface of the case 11 may also be provided with a recessed opening that does not penetrate through the upper surface of the case 11, in order to reduce the weight of the case 11 and to reduce the constituent material of the case 11.

As illustrated in FIG. 3B, the semiconductor elements 13a to 13h are mounted on a main surface of the insulated circuit substrate 20. The main surface of the insulated circuit substrate 20 is the front surfaces (upper surfaces) of conductive pattern layers 20a1 to 20a3. The upper surfaces of the semiconductor elements 13a to 13h and the conductive pattern layers 20a1 to 20a3 are at least partly covered by the case 11.

The semiconductor elements 13a, 13b, 13e, and 13f are bonded to the front surface of the conductive pattern layer 20a1 by a bonding member (for example, a bonding member 15b in FIG. 2) such as solder or a sintered material (copper or silver). The semiconductor elements 13c, 13d, 13g, and 13h are bonded to the front surface of the conductive pattern layer 20a2 by a bonding member such as solder or a sintered material.

The semiconductor elements 13a to 13h may be power metal-oxide-semiconductor field-effect transistors (MOSFETs) made mainly of silicon carbide. In the power MOSFET, the body diode may function as a free-wheeling diode (FWD). The semiconductor elements 13a to 13h may include switching elements made mainly of silicon. A switching element may be, for example, a reverse-conducting (RC)-IGBT. The RC-IGBT has both functions of the IGBT and the FWD. Each of the semiconductor elements 13a to 13h may be a semiconductor chip including a set of a switching element and a diode element that are made mainly of silicon. The switching element is, for example, a power MOSFET or an IGBT. As the diode element, for example, a Schottky barrier diode (SBD) or a P-intrinsic-N (PiN) diode is used as the FWD. 43 Although not illustrated, main electrodes and control electrodes are provided on the front surfaces of the semiconductor elements 13a to 13h. In the case where the semiconductor elements 13a to 13h are IGBTs, the main electrodes are emitter electrodes. In the case where the semiconductor elements 13a to 13h are power MOSFETs, the main electrodes are source electrodes. The main electrodes on the front surfaces are bonded to the printed board 30 by a bonding member (for example, a bonding member 15c in FIG. 2) such as solder or a sintered material, so that they are electrically connected to any of the terminals 12a to 12c via the printed board 30. The control electrodes are the gate electrodes of switching elements included in the semiconductor elements 13a to 13h. The control electrodes are bonded to the printed board 30 by a bonding member such as solder or a sintered material, so that they are electrically connected to a control terminal, which is not illustrated, via the printed board 30. In this connection, the main electrodes and the control electrodes on the front surfaces of the semiconductor elements 13a to 13h may be bonded to the printed board 30 via pin-shaped connection members that are bonded by bonding members.

Although not illustrated, main electrodes are also provided on the back surfaces of the semiconductor elements 13a to 13h. In the case where the semiconductor elements 13a to 13h are IGBTs, the main electrodes on their back surfaces are collector electrodes. In the case where the semiconductor elements 13a to 13h are power MOSFETs, the main electrodes on their back surfaces are drain electrodes. The main electrodes on the back surfaces of the semiconductor elements 13a to 13h are electrically connected to any of the terminals 12a to 12c via the conductive pattern layers 20a1 to 20a3, pin-shaped connection members (for example, connection members 14a and 14b in FIGS. 2 and 3B), or the printed board 30.

Note that the number of semiconductor elements is not limited to that in the above-described configuration. An appropriate number of semiconductor elements are provided for the specifications of the semiconductor module 1a. Other semiconductor elements such as diode elements may be mounted on the insulated circuit substrate 20.

The insulated circuit substrate 20 has a rectangular shape in plan view. As illustrated in FIGS. 2 and 3B, the insulated circuit substrate 20 includes the conductive pattern layers 20a1 to 20a3, a metal layer 20b, and an insulating layer 20c sandwiched between the metal layer 20b and the conductive pattern layers 20a1 to 20a3, which are at least partly covered by the case 11.

Preferably, the edges of the conductive pattern layers 20a1 to 20a3 facing the outer periphery of the insulating layer 20c are aligned with the edges of the metal layer 20b facing the outer periphery of the insulating layer 20c in plan view. Therefore, the insulated circuit substrate 20 maintains stress balance with the metal layer 20b provided on the back surface of the insulating layer 20c, thereby suppressing damage such as excessive warping or cracking of the insulating layer 20c.

The conductive pattern layers 20a1 to 20a3 are made of a metal having excellent electrical conductivity. Such a metal is, for example, copper, aluminum, or an alloy containing at least one of these metals.

The terminal 12c is bonded to the conductive pattern layer 20a1, the terminal 12b is bonded to the conductive pattern layer 20a2, and the terminal 12a is bonded to the conductive pattern layer 20a3 by a bonding member (for example, a bonding member 15a as illustrated in FIG. 2) such as solder or a sintered material. Instead of using such a bonding member, the bonding may be performed by ultrasonic bonding.

The metal layer 20b has a rectangular shape in plan view. Further, the corner portion may be rounded or chamfered. The metal layer 20b is smaller in size than the insulating layer 20c and is formed on the entire surface of the insulating layer 20c except for the edge portion thereof. The metal layer 20b is made mainly of a metal having excellent thermal conductivity. Such a metal is, for example, copper, aluminum, or an alloy containing at least one of these metals.

The insulating layer 20c has a rectangular shape in plan view. Corner portions of the insulating layer 20c may be rounded or C-chamfered. The insulating layer 20c is made of an insulating resin. The insulating resin may be a material having low thermal resistance and high insulating property. For example, such a resin is a thermosetting resin. Examples of the thermosetting resin include at least one of an epoxy resin, a cyanate resin, a polyimide resin, a benzoxazine resin, an unsaturated polyester resin, a phenol resin, a melamine resin, a silicone resin, and a maleimide resin. The thermosetting resin may further contain a filler. The filler is made of at least one of an oxide and a nitride. Examples of the oxide include silicon oxide and aluminum oxide. Examples of the nitride include silicon nitride, aluminum nitride, and boron nitride. Further, hexagonal boron nitride may be used as the filler.

An insulating plate containing ceramics as a main component may be used as the insulating layer 20c of the insulated circuit substrate 20. Such ceramics are made of a material containing, for example, aluminum oxide, aluminum nitride, or silicon nitride as a main component. In this case, for example, a direct copper bonding (DCB) substrate, an active metal brazed (AMB) substrate, or the like may be used as the insulated circuit substrate 20.

The conductive pattern layers 20a 1 and 20a2 of the insulated circuit substrate 20 have the third openings 20d1 and 20d2 at the same positions as the first openings 11a1 and 11a2 in plan view. As illustrated in FIG. 2, the third opening 20d1 does not penetrate through the conductive pattern layer 20a2. However, the third opening 20d 1 may penetrate through the conductive pattern layer 20a2 to reach the insulating layer 20c. The same applies to the third opening 20d2. The diameters of the third openings 20d 1 and 20d2 correspond to the diameters of the positioning members (for example, approximately 1 to 2 mm).

The shapes of the third openings 20d 1 and 20d2 in plan view are not limited to a circular shape as illustrated in FIG. 3B. The shapes of the third openings 20d1 and 20d2 in plan view may be a shape other than a circular shape, such as a quadrangular shape. The number of third openings 20d1 and 20d2 is not limited to two.

Since these third openings 20d 1 and 20d2 are formed, the semiconductor elements 13a to 13h, whose upper surfaces are at least partly covered by the case 11, are provided in a region other than the regions directly below the first openings 11a1 and 11a 2.

In addition, connection members (the connection members 14a and 14b in FIGS. 2 and 3B, and others) that extend in the +Z direction to electrically connect the insulated circuit substrate 20 to the printed board 30 may be provided on the main surface of the insulated circuit substrate 20. For example, as illustrated in FIG. 2, one end of the connection member 14a is bonded to one side of the conductive pattern layer 20a1, and the other end of the connection member 14a is bonded to the conductive pattern layer 30a2 of the printed board 30. These connection members are provided in a region other than the regions directly below the first openings 11a1 and 11a 2. The connection members electrically connect one of the conductive pattern layers 20a1 to 20a3 to the semiconductor elements 13a to 13h, or electrically connects the conductive pattern layers 20a1 to 20a3 to one another. Wire bonds may be used as the connection members.

The printed board 30 is also a part of the connection members. The printed board 30 is provided to face the main surface of the insulated circuit substrate 20 inside the case 11. The printed board 30 includes conductive pattern layers 30a 1 to 30a3 on the back surface thereof, a conductive pattern layer 30b on the front surface thereof, and an insulating layer 30c provided between the conductive pattern layers 30a 1 to 30a3 and the conductive pattern layer 30b.

The conductive pattern layers 30a 1 to 30a3 are electrically connected to the semiconductor elements 13a to 13h or the conductive pattern layers 20a1 and 20a3 of the insulated circuit substrate 20. The conductive pattern layer 30b is electrically connected to any one of the conductive pattern layers 30a 1 to 30a3 through via holes provided in the insulating layer 30c, for example. Although not illustrated, the conductive pattern layer 30b is electrically connected to, for example, an external connection terminal such as a control terminal.

The conductive pattern layers 30a 1 to 30a3 and 30b are made of a metal having excellent electrical conductivity. Such a metal is, for example, copper, aluminum, or an alloy containing at least one of these metals as a main component.

The insulating layer 30c is made of, for example, an insulating resin. As the insulating layer using an insulating resin, for example, a paper phenol substrate, a paper epoxy substrate, a glass composite substrate, or a glass epoxy substrate may be used.

The printed board 30 may have a multilayer structure in which one or more conductive pattern layers are also formed inside the insulating layer 30c.

The printed board 30 has the second openings 30d1 and 30d 2 at the same positions as the first openings 11a1 and 11a2 in plan view. As illustrated in FIG. 2, the second opening 30d1 is a through hole. The same applies to the second opening 30d2. The diameters of the second openings 30d1 and 30d2 correspond to the diameters of the positioning members (for example, approximately 1 to 2 mm).

The shapes of the second openings 30d 1 and 30d 2 in plan view are not limited to a circular shape as illustrated in FIG. 3A. The shapes of the second openings 30d1 and 30d2 in plan view may be a shape other than a circular shape, such as a quadrangular shape. The number of second openings 30d1 and 30d2 is not limited to two.

The sealing resin 40 fills the case 11 to seal the semiconductor elements 13a to 13h, the insulated circuit substrate 20, and the printed board 30. The first openings 11a1 and 11a 2, the second openings 30d 1 and 30d 2, and the third openings 20d 1 and 20d2 are also filled with the sealing resin 40. In the case where the sealing is performed by transfer molding, the sealing resin 40 is not a soft resin such as gel but a rigid resin. As the rigid resin, for example, a thermosetting resin such as an epoxy resin is used.

In manufacturing the above-described semiconductor module 1a, the positioning between the case 11, the semiconductor elements 13a to 13h, the insulated circuit substrate 20, and the printed board 30 is performed using the positioning members in a bonding step.

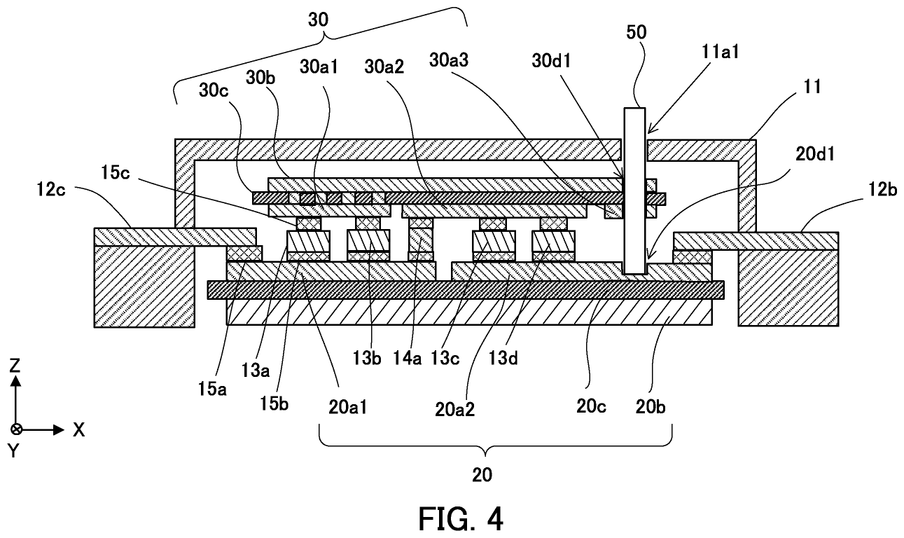

FIG. 4 illustrates how to perform the positioning using positioning members.

First, the insulated circuit substrate 20 is mounted on a jig used for bonding (not illustrated), and bonding members (such as the bonding members 15a and 15b) such as solder are disposed on the insulated circuit substrate 20. Then, the semiconductor elements 13a to 13h and pin-shaped connection members (such as the connection member 14a) are disposed on the bonding members. Further, bonding members (such as the bonding member 15c) are disposed thereon.

A pin-shaped positioning member 50 is set in the third opening 20d1. As illustrated in FIG. 4, for example, the positioning member 50 is fixed in a state where a tip of the positioning member 50 is inserted into the third opening 20d1 of the insulated circuit substrate 20. Although not illustrated in FIG. 4, another pin-shaped positioning member is similarly set in the third opening 20d2 illustrated in FIG. 3B.

Thereafter, the printed board 30 is set over the insulated circuit substrate 20 while the positioning member 50 is inserted into the second opening 30d1. Although not illustrated in FIG. 4, the other pin-shaped positioning member is similarly inserted into the second opening 30d2 illustrated in FIG. 3A. In addition, the case 11 is set while the positioning member 50 is inserted into the first opening 11a1. Although not illustrated in FIG. 4, the other pin-shaped positioning member is similarly inserted into the first opening 11a2 illustrated in FIG. 1. As a result, the state illustrated in FIG. 4 is obtained. In this state, the respective portions are bonded by the bonding members.

Since the case 11 has the first openings 11a1 and 11a2 and the insulated circuit substrate 20 has the third openings 20d 1 and 20d2 as described above, the terminals 12a to 12c of the case 11 are bonded to the insulated circuit substrate 20 at their appropriate positions. In addition, since the case 11 has the first openings 11a1 and 11a 2 and

the printed board 30 has the second openings 30d1 and 30d2, the insulated circuit substrate 20 and the printed board 30 are fixed to have an appropriate positional relationship. Thus, the printed board 30 is bonded to the semiconductor elements 13a to 13h and the connection members disposed on the insulated circuit substrate 20, at their appropriate positions.

After the bonding step as described above, the positioning member 50 is removed, and a sealing step using transfer molding is performed. At this time, the following problems may occur.

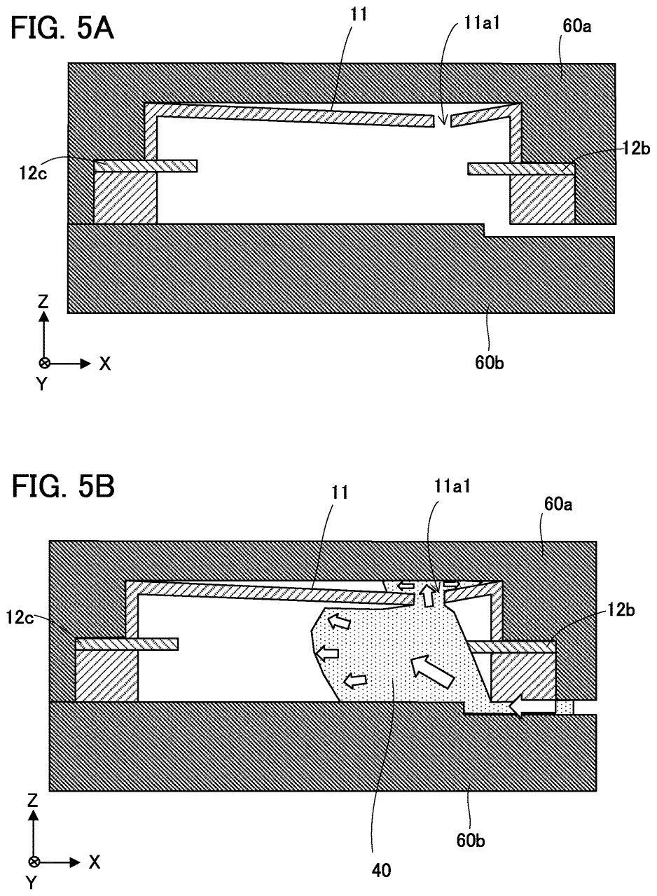

FIGS. 5A and 5B illustrate a problem in manufacturing the semiconductor module of the comparative example. FIG. 5A illustrates an example in which the semiconductor module 1a of the comparative example that is not filled with the sealing resin 40 is clamped between an upper mold 60a and a lower mold 60b. FIG. 5B illustrates a state in which the sealing resin 40 is injected into the case 11. Arrows in FIG. 5B indicate an example of directions in which the sealing resin 40 spreads. In FIGS. 5A and 5B, the components (the semiconductor elements 13a to 13h, the insulated circuit substrate 20, the printed board 30, and others) inside the case 11 are not illustrated.

In the semiconductor module 1a of the comparative example, the first opening 11a1, into which the positioning member 50 is inserted, is provided in the upper surface of the case 11 as described above. In the sealing step, in order to inhibit the sealing resin 40 from leaking through the first opening 11a1, it is desirable to reduce the gap between the upper surface of the case 11 and the upper mold 60a as much as possible by applying pressure using the upper mold 60a.

However, as illustrated in FIG. 5A, a peripheral portion of the first opening 11a1 formed in the upper surface of the case 11 may sink toward the lower mold 60b due to variations in component dimensions in the Z direction or warpage or undulation of the upper surface of the case 11. In this case, a gap may be formed between the peripheral portion of the first opening 11a1 formed in the upper surface of the case 11 and the upper mold 60a. If this happens, as illustrated in FIG. 5B, the sealing resin 40 may leak from the inside of the case 11 to the gap through the first opening 11a1. If the sealing resin 40 leaks, the leaked resin remains as a resin burr around the first opening 11a1 on the upper surface of the case 11 after curing of the sealing resin 40, which causes a molding defect.

A semiconductor module according to a first embodiment, which will be described below, is able to prevent a molding defect caused by leakage of a sealing resin out of a case during transfer molding. In addition, the semiconductor module of the first embodiment is also able to reduce the cost needed for measures against leakage of the sealing resin.

### First Embodiment

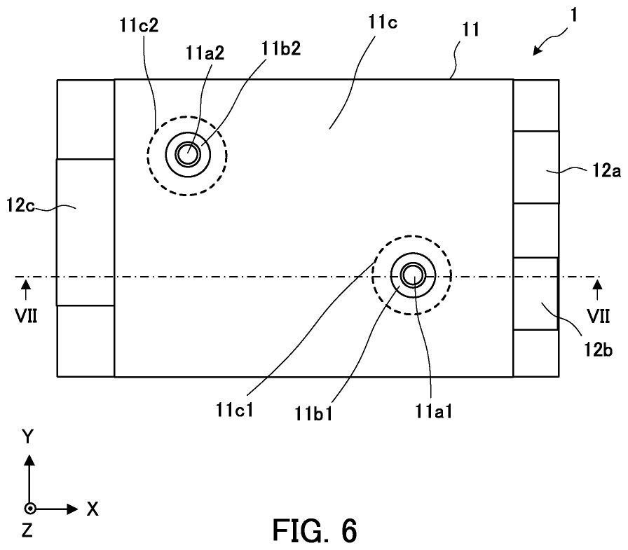

FIG. 6 is a plan view of the semiconductor module according to the first embodiment, before mold clamping.

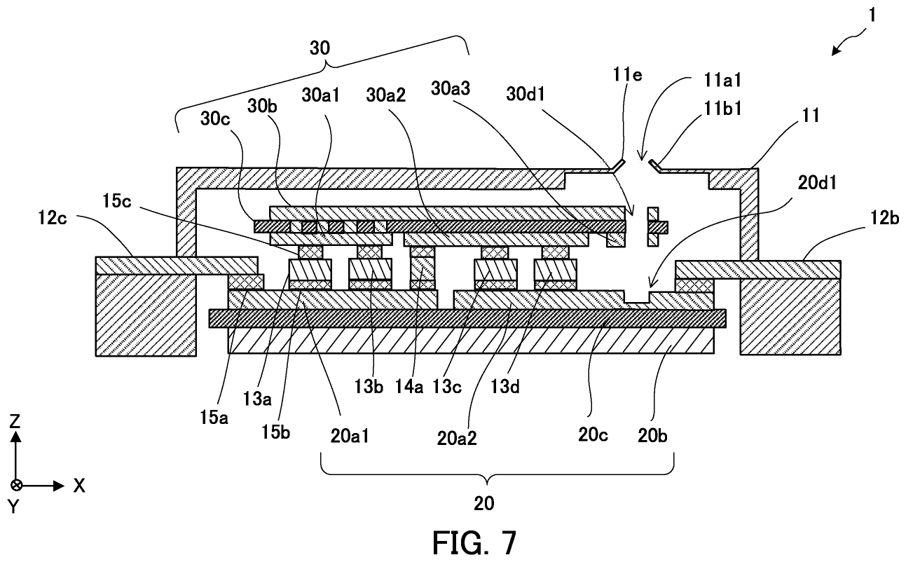

FIG. 7 is a sectional view of the semiconductor module according to the first embodiment, taken along a line VII-VII of FIG. 6 before mold clamping. In FIGS. 6 and 7, the same elements as those illustrated in FIGS. 1 and 2 are denoted by the same reference numerals.

A case 11 of the semiconductor module 1 according to the first embodiment has a first region 11c and second regions 11c1 and 11c 2 that are thinner than the first region 11c, on the upper surface thereof. The first region 11c has a thickness needed for molding at least this region, which is, for example, in the range of 1 mm to 2 mm, inclusive. On the other hand, the second regions 11c1 and 11c 2 may have a thickness of, for example, 0.2 mm to 0.3 mm, inclusive because these regions are small. Since the second regions 11c1 and 11c 2, which are thinner than the first region 11c, are parts of the upper surface of the case 11, the strength of the case 11 is maintained.

In this connection, the upper surface of the case 11 may have other regions thinner than the first region 11c, in addition to the second regions 11c1 and 11c 2.

Further, in the case 11, first openings 11a1 and 11a2, into which positioning members are inserted, are provided in the second regions 11c1 and 11c 2. As described earlier, the diameters of the first openings 11a1 and 11a 2 are determined according to the diameters of the positioning members to be used, and are preferably, for example, in the range of 1 mm to 2 mm, inclusive. The shapes of the first openings 11a1 and 11a 2 in plan view are not limited to a circular shape as illustrated in FIG. 6. The shapes of the first openings 11a1 and 11a 2 in plan view may be a shape other than a circular shape, such as a quadrangular shape. The number of first openings is not limited to two. Note, however, that at least two first openings are preferably provided in order to achieve accurate positioning.

Further, the second region 11c1 includes a raised region 11b1 on a central-axis side thereof where the central axis of the first opening 11a1 is located. The raised region 11b1 surrounds the first opening 11a1 and rises upward relative to the upper surface of the first region 11c, as illustrated in FIG. 7. The position of an upper end 11e of the raised region 11b1 in the Z direction is preferably a position corresponding to the size of a gap that may be generated between the upper surface of the first region 11c and an upper mold 60a due to warpage of the case 11 or the like. For example, the raised region 11b1 is formed such that the upper end 11e in the Z direction is located at a height of 0.3 mm or more and 0.5 mm or less in the +Z direction from the upper surface of the first region 11c.

Similarly, the second region 11c2 includes a raised region 11b2 on a central-axis side thereof where the central axis of the first opening 11a2 is located. The raised region 11b2 surrounds the first opening 11a2 and rises upward relative to the upper surface of the first region 11c.

Since the semiconductor module 1 according to the first embodiment has the case 11 having the above-described structure before the mold clamping, the following effects are obtained.

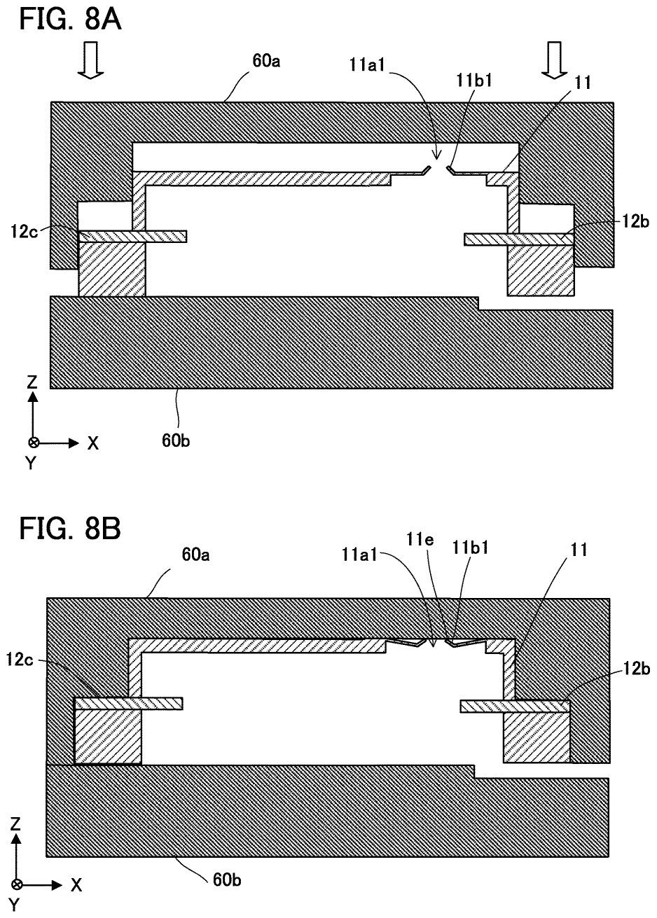

FIGS. 8A and 8B illustrate states of the semiconductor module according to the first embodiment, during the mold clamping. FIG. 8A illustrates a state of the case 11 before the semiconductor module 1 of the first embodiment, which is not filled with the sealing resin 40, is clamped between the upper mold 60a and a lower mold 60b. FIG. 8B illustrates a state of the case 11 in which the semiconductor module 1 of the first embodiment, which is not filled with the sealing resin 40, is clamped between the upper mold 60a and the lower mold 60b. In FIGS. 8A and 8B, components (semiconductor elements 13a to 13h, insulated circuit substrate 20, printed board 30, and others) inside the case 11 are not illustrated.

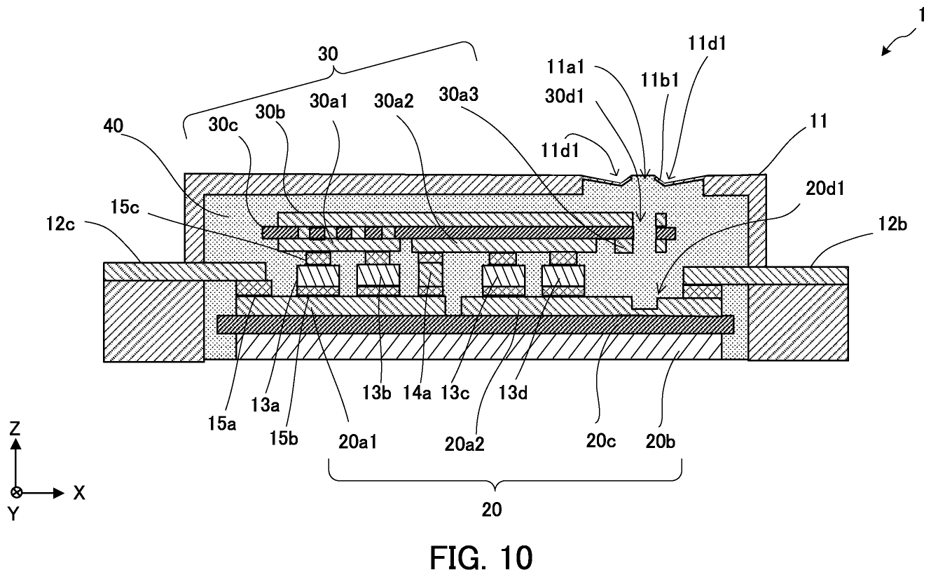

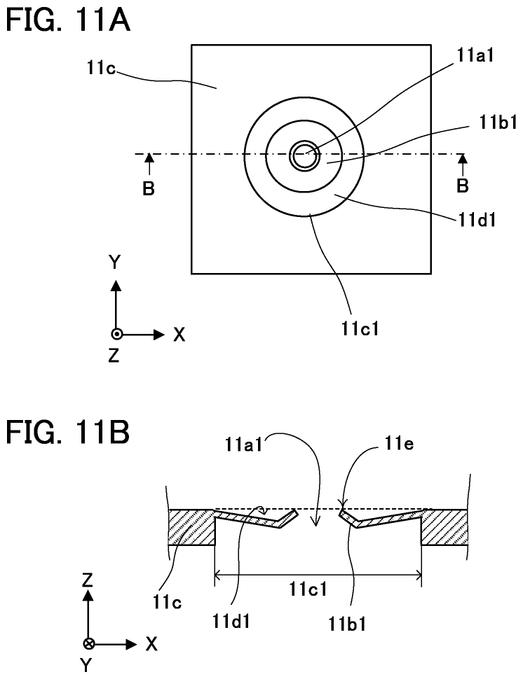

As illustrated in FIG. 8A, the upper surface of the case 11 is pressed in the arrow direction (in the −Z direction) by the main surface of the upper mold 60a facing the upper surface of the case 11. The second region 11c1 is thinner than the first region 11c, and thus has lower rigidity than the first region 11c. Therefore, as illustrated in FIG. 8B, the raised region 11b1 is pushed downward (in the −Z direction) with the vicinity of the boundary between the first region 11c and the second region 11c1 as a fulcrum. At this time, the raised region 11b1 of the second region 11c1 pushed downward (in the −Z direction) with the vicinity of the boundary as a fulcrum pushes back the main surface of the upper mold 60a upward (in the +Z direction) by the elastic force. That is, by pressing with the upper mold 60a, the upper end 11e of the raised region 11b1 and the main surface of the upper mold 60a are brought into contact with each other. Although not illustrated, the raised region 11b2 is also pushed downward (in the −Z direction), so that the upper end of the raised region 11b2 and the main surface of the upper mold 60a are brought into contact with each other. In addition, by pressing with the upper mold 60a, a recess (see FIGS. 10, 11A and 11B to be described later) that annularly surrounds the first opening 11a1 is formed in the second region 11c1.

In the manufacturing method for the semiconductor module 1 according to the first embodiment, the sealing resin 40 injected into the case 11 in this state. The sealing resin 40 here is a thermosetting resin such as an epoxy resin.

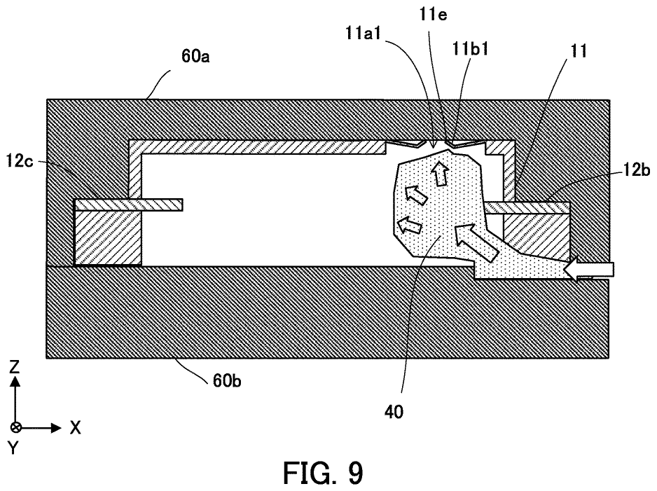

FIG. 9 illustrates a state in which the sealing resin is injected into the case of the semiconductor module of the first embodiment. In the example of FIG. 9, an injection port (also referred to as a gate port) for the sealing resin 40 is provided on a short side of the case 11, but may alternatively be provided on a long side of the case 11.

By pressing with the upper mold 60a, the upper end 11e of the raised region 11b1 and the main surface of the upper mold 60a are brought into contact with each other, thereby closing the gap between the upper surface of the case 11 and the main surface of the upper mold 60a. Thus, the sealing resin 40 injected into the case 11 is inhibited from leaking out of the case 11 through the first opening 11a1, by the raised region 11b1 and the main surface of the upper mold 60a in the first opening 11a1. As a result, a molding defect caused by such leakage of the sealing resin 40 out of the case 11 is prevented.

In addition, by pressing with the upper mold 60a in the first opening 11a1, the recess that annularly surrounds the first opening 11a1 is formed in the second region 11c1. Therefore, even if the sealing resin 40 flows over the upper end 11e and leaks to the outside of the case 11, the sealing resin 40 flows into the recess. This inhibits the sealing resin 40 from leaking and spreading to the outside of the recess in plan view.

FIG. 10 is a sectional view of the semiconductor module according to the first embodiment. FIGS. 11A and 11B are a plan view and a sectional view, respectively, of a peripheral portion of the first opening formed in the case of the semiconductor module according to the first embodiment, in a state after mold clamping. FIG. 11A is a plan view of the peripheral portion of the first opening, and FIG. 11B is a sectional view taken along a line B-B of FIG. 11A. In FIG. 11B, the sealing resin 40 is not illustrated.

As illustrated in FIG. 10, the sealing resin 40 fills up to the upper surface of the inner wall of the case 11, and has a sealing surface in the first opening 11a1, the sealing surface being level with the upper surface of the outer wall of the case 11.

After the molding, the case 11 has, in addition to the first opening 11a1, a recess 11d1 annularly surrounding the first opening 11a1, in the second region 11c1 of the upper surface of the case 11, and is fixed by curing the rigid sealing resin 40. This recess 11d1 is formed by pressing with the upper mold 60a. As illustrated in FIG. 9, during injection of the sealing resin 40 into the case 11, the recess 11d1 inhibits the sealing resin 40 from leaking and spreading to the outside of the recess 11d1 in plan view. Having this effect, the recess 11d1 may have the sealing resin 40 therein. Although not illustrated, similarly, the second region 11c2 has, in addition to the first opening 11a2, a recess annularly surrounding the first opening 11a1.

In addition, the case 11 has, in the second region 11c1, the annular raised region 11b1 that rises upward from the recess 11d1 toward the central axis of the first opening 11a1. The second region 11c1 has the upper end 11e that is level with the upper surface of the first region 11c, at a position closer to the first opening 11a1 than the position of the recess 11d1 in plan view. In the semiconductor module 1 of the first embodiment, the upper end 11e corresponds to the upper end of the raised region 11b1.

During injection of the sealing resin 40 into the case 11, this upper end 11e and the main surface of the upper mold 60a are in contact with each other, thereby closing the gap between the upper surface of the case 11 and the main surface of the upper mold 60a. This inhibits the sealing resin 40 from leaking out of the case 11 through the first opening 11a1. Thus, in the semiconductor module 1, a molding defect caused by such leakage of the sealing resin 40 out of the case 11 is prevented.

Further, the above-described measures against leakage of the sealing resin 40 do not need any additional component, or do not impose strict component manufacturing tolerances. Therefore, an increase in product cost is suppressed.

### Second Embodiment

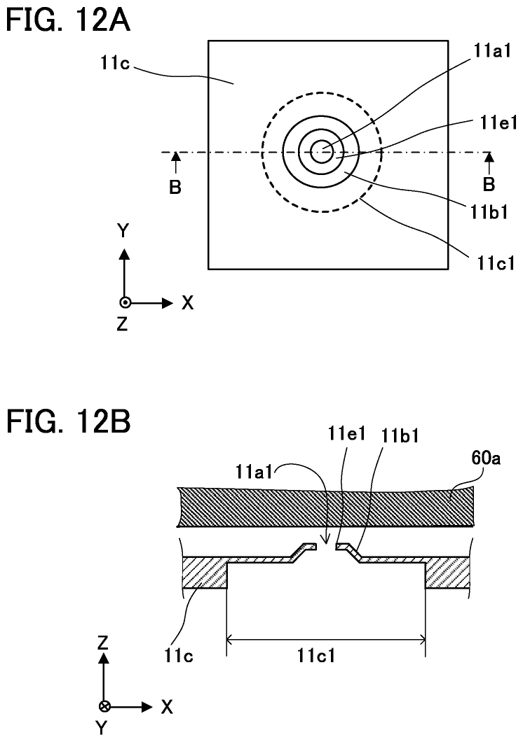

FIGS. 12A and 12B are a plan view and a sectional view, respectively, of a peripheral portion of a first opening formed in a case of a semiconductor module according to a second embodiment, in a state before mold clamping. FIG. 12A is a plan view of the peripheral portion of the first opening, and FIG. 12B is a sectional view taken along a line B-B of FIG. 12A. In FIG. 12B, an upper mold 60a is also illustrated. In FIGS. 12A and 12B, components other than the case 11 are the same as those of the semiconductor module 1 of the first embodiment, and thus the illustration thereof is omitted.

In the semiconductor module of the second embodiment, the case 11 has a raised region 11b1 in a second region 11c1 of the upper surface thereof, as in the semiconductor module 1 of the first embodiment. Further, in the second embodiment, as illustrated in FIGS. 12A and 12B, the case 11 has an annular first portion 11e1 that is located on the central-axis side of the raised region 11b1 where the central axis of the first opening 11a1 is located. The first portion 11e1 surrounds the first opening 11a1 and is parallel to the upper surface of the case 11. In this connection, the first portion 11e1 may be formed as an arch-shaped portion having an upwardly convex curvature relative to the upper surface of the case 11 in a sectional view.

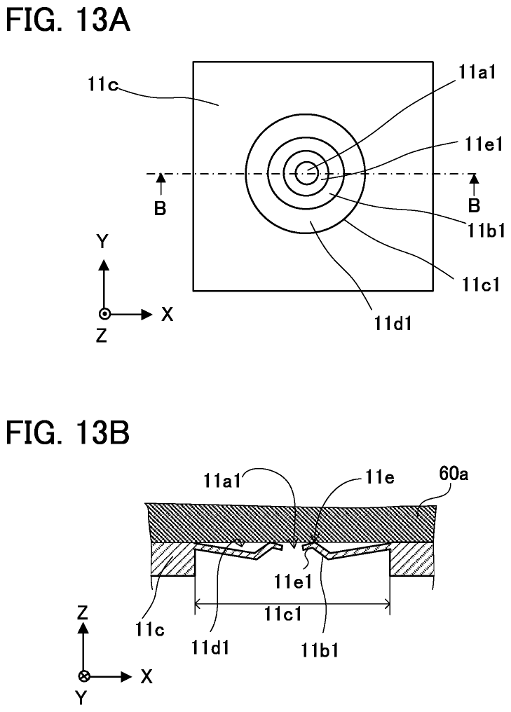

FIGS. 13A and 13B are a plan view and a sectional view, respectively, of the peripheral portion of the first opening formed in the case of the semiconductor module according to the second embodiment, in a state after mold clamping. FIG. 13A is a plan view of the peripheral portion of the first opening, and FIG. 13B is a sectional view taken along a line B-B of FIG. 13A. In FIG. 13B, the upper mold 60a is also illustrated.

In a step of injecting the sealing resin, the upper mold 60a presses the first portion 11e1 to push the raised region 11b1 together with the first portion 11e1 downward (in the −Z direction) from the upper surface of the case 11. As a result, as in the semiconductor module 1 of the first embodiment, the case 11 has a recess 11d1 that annularly surrounds the first opening 11a1, in the second region 11c1. The first portion 11e1 is inclined downward toward the central axis of the first opening 11a1. Thereafter, the sealing resin 40 is injected into the case 11. 101 In the semiconductor module of the second embodiment, the first portion 11e1 is formed as described above, thereby increasing a contact area between the second region 11c1 and the upper mold 60 a when the first portion 11e1 is pressed by the upper mold 60a, compared to the semiconductor module 1 of the first embodiment. Thus, it is possible to further inhibit the sealing resin 40 from leaking out of the case 11 through the first opening 11a1.

### Third Embodiment

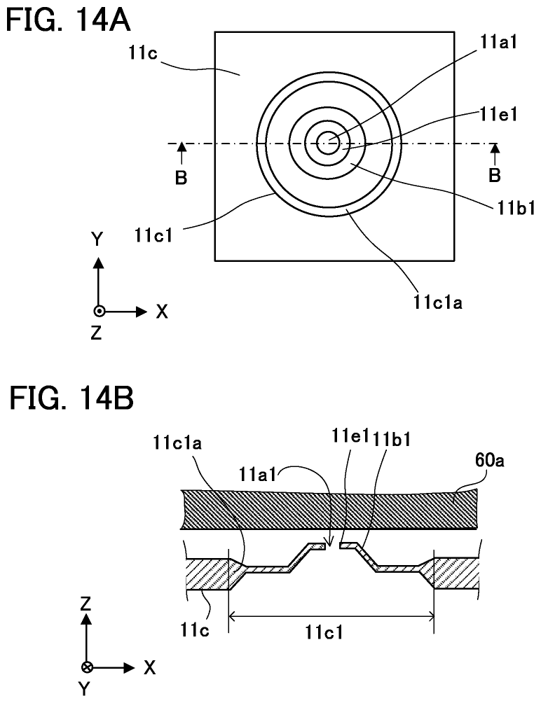

FIGS. 14A and 14B are a plan view and a sectional view, respectively, of a peripheral portion of a first opening formed in a case of a semiconductor module according to a third embodiment, in a state before mold clamping. FIG. 14A is a plan view of the peripheral portion of the first opening, and FIG. 14B is a sectional view taken along a line B-B of FIG. 14A. In FIG. 14B, an upper mold 60a is also illustrated. In FIG. 14, components other than the case 11 are the same as those of the semiconductor module 1 of the first embodiment, and thus the illustration thereof is omitted.

In the semiconductor module of the third embodiment, the case 11 has a raised region 11b1 in a second region 11c1 of the upper surface thereof, as in the semiconductor module 1 of the first embodiment. In addition, in the third embodiment, as in the second embodiment, the case 11 has an annular first portion 11e1 that is located on the central-axis side of the raised region 11b where the central axis of the first opening 11a1 is located. The first portion 11e1 surrounds the first opening 11a1 and is parallel to the upper surface of the case 11. In this connection, the first portion 11e1 may be formed as an arch-shaped portion having an upwardly convex curvature relative to the upper surface of the case 11 in a sectional view.

Further, in the third embodiment, the second region 11c1 includes a connection region 11c1a that is continuous with the first region 11c. The connection region 11c1a has an upper surface that descends from the same height as the upper surface of the first region 11c to a height lower than the upper surface of the first region 11c, toward the central axis of the first opening 11a1. In addition, the connection region 11c1a has a thickness that decreases toward the central axis of the first opening 11a1.

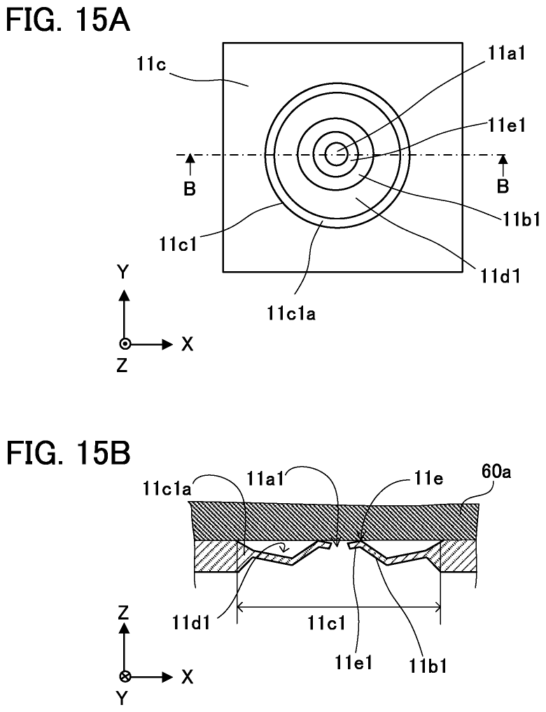

FIGS. 15A and 15B are a plan view and a sectional view, respectively, of the peripheral portion of the first opening formed in the case of the semiconductor module according to the third embodiment, in a state after mold clamping. FIG. 15A is a plan view of the peripheral portion of the first opening, and FIG. 15B is a sectional view taken along a line B-B of FIG. 15A. In FIG. 15B, the upper mold 60a is also illustrated.

In the step of injecting the sealing resin, the upper mold 60a presses the first portion 11e1 to push the raised region 11b1 together with the first portion 11e1 downward (in the −Z direction) from the upper surface of the case 11. As a result, as in the semiconductor module 1 of the first embodiment, the case 11 has a recess 11d1 that annularly surrounds the first opening 11a1, in the second region 11c1. Thereafter, the sealing resin 40 is injected into the case 11.

In the semiconductor module of the third embodiment, the second region 11c1 includes the connection region 11c1a. The upper surface of the connection region 11c1a descends from the same height as the upper surface of the first region 11c to a height lower than the upper surface of the first region 11c, toward the central axis of the first opening 11a1. The thickness of the connection region 11c1a decreases toward the central axis of the first opening 11a1. With the above-described connection region 11c1a, the formed recess 11d1 has a larger average depth than those formed in the first embodiment and the second embodiment.

In this connection, the connection region 11c1a as described above may be omitted. Instead, the second region 11c1 having a constant thickness may connect to the first region 11c at a position lower than the upper surface of the first region 11c.

Therefore, during injection of the sealing resin 40 into the case 11, the recess 11d1 inhibits the sealing resin 40 from leaking and spreading to the outside of the recess 11d1 in plan view, compared to the first embodiment and the second embodiment.

### Fourth Embodiment

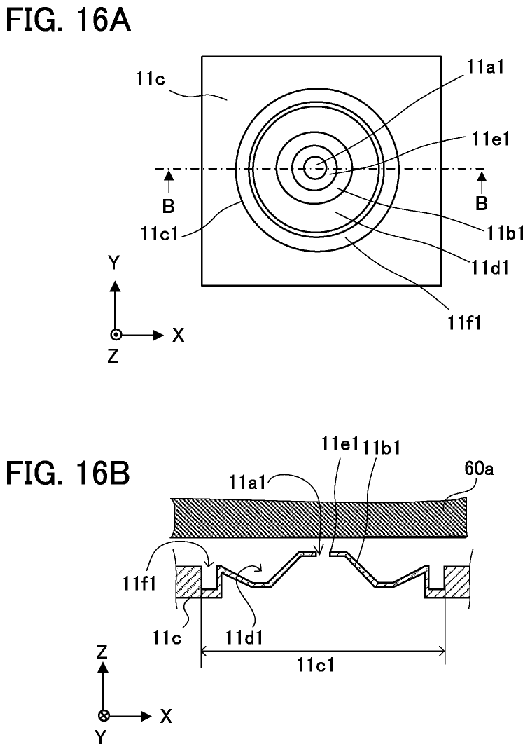

FIGS. 16A and 16B are a plan view and a sectional view, respectively, of a peripheral portion of a first opening formed in a case of a semiconductor module according to a fourth embodiment, in a state before mold clamping. FIG. 16A is a plan view of the peripheral portion of the first opening, and FIG. 16B is a sectional view taken along a line B-B of FIG. 16A. In FIG. 16B, an upper mold 60a is also illustrated. In FIGS. 16A and 16B, components other than the case 11 are the same as those of the semiconductor module 1 of the first embodiment, and thus the illustration thereof is omitted.

In the semiconductor module of the fourth embodiment, a case 11 has a raised region 11b1 in a second region 11c1 of the upper surface thereof, as in the semiconductor module 1 of the first embodiment. In addition, in the fourth embodiment, as in the second embodiment, the case 11 has an annular first portion 11e1 that is located on the central-axis side of the raised region 11b1 where the central axis of the first opening 11a1 is located. The first portion 11e1 surrounds the first opening 11a1, and is parallel to the upper surface of the case 11. In this connection, the first portion 11e1 may be formed as an arch-shaped portion having an upwardly convex curvature relative to the upper surface of the case 11 in a sectional view. 114 Further, in the fourth embodiment, the second region 11c1 has an annular recess 11d1 provided to surround the first opening 11a1 at a position farther from the first opening 11a1 than the position of the raised region 11b1, and a groove 11f1 provided at a position farther from the first opening 11a1 than the position of the recess 11d1. The groove 11f1 continuously and annularly surrounds the first opening 11a1 and the recess 11d1 in the second region 11c1.

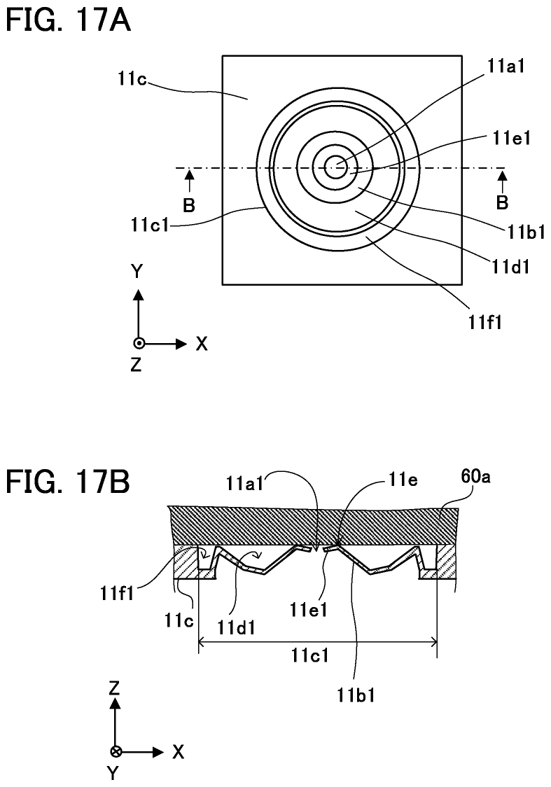

FIGS. 17A and 17B are a plan view and a sectional view, respectively, of the peripheral portion of the first opening formed in the case of the semiconductor module according to the fourth embodiment, in a state after mold clamping. FIG. 17A is a plan view of the peripheral portion of the first opening, and FIG. 17B is a sectional view taken along a line B-B of FIG. 17A. In FIG. 17B, the upper mold 60a is also illustrated.

In the step of injecting the sealing resin, the upper mold 60a presses the first portion 11e1 to push the raised region 11b1 together with the first portion 11e1 downward (in the −Z direction) from the upper surface of the case 11. As a result, the recess 11d1 has an average depth greater than that before the mold clamping. Thereafter, the sealing resin 40 is injected in to the case 11.

In the semiconductor module of the fourth embodiment, the average depth of the recess 11d1 formed after the mold clamping is greater than those obtained in the first embodiment and the second embodiment. Therefore, during injection of the sealing resin 40 into the case 11, the recess 11d1 further inhibits the sealing resin 40 from leaking and spreading to the outside of the recess 11d1 in plan view, compared to the first embodiment and the second embodiment.

Furthermore, in the semiconductor module of the fourth embodiment, the case 11 has the groove 11f1 in the upper surface thereof at a position farther from the first opening 11a1 than the position of the recess 11d1. The groove 11f1 allows the second region 11c1 to deform more easily when the first portion 11e1 is pressed by the upper mold 60a, thereby allowing the recess 11d1 to be formed with a greater average depth.

In addition, even if the sealing resin 40 leaks to the outside of the recess 11d1, the sealing resin 40 enters the groove 11f1, so that the sealing resin 40 is inhibited from leaking and spreading on the upper surface of the case 11.

Although the cases 11 of the third and fourth embodiments each have the first portion 11e1, as in the case 11 of the second embodiment, the first portion 11e1 may be omitted.

Here, the first to fourth embodiments may be combined. For example, in the case where the two first openings 11a1 and 11a2 are formed in the upper surface of the case 11 as illustrated in FIG. 6, different embodiments may be applied to the second regions 11c1 and 11c 2. For example, the connection region 11c1a as described in the third embodiment may be provided in the second region 11c1, and the recess 11d1 and the groove 11f1 as described in the fourth embodiment may be provided in the second region 11c2.

The above describes, as an example, the printed board 30 as a part of the connection members. Alternatively, instead of using the printed board 30, another connection member or wiring member such as a wire bond or a lead frame may be used.

### Manufacturing Method for Semiconductor Module

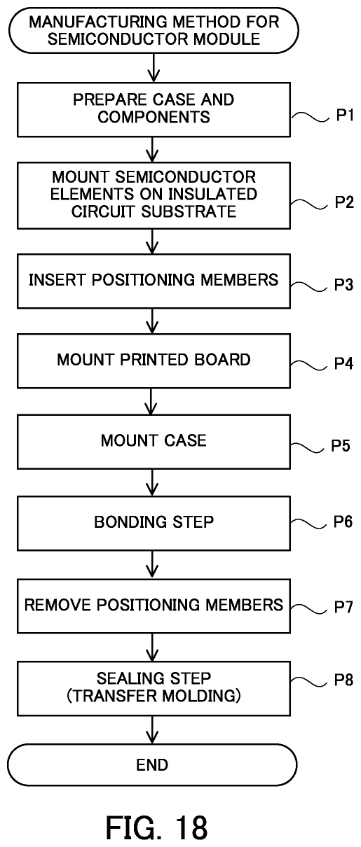

FIG. 18 illustrates a manufacturing process for a semiconductor module.

[Step P1] A step of preparing the case 11 and components having the second openings is performed. The case 11 has the first region 11c and the second regions 11c1 and 11c2, which are thinner than the first region 11c, on the upper surface thereof (see, for example, FIG. 6). The case 11 is provided with the first openings 11a1 and 11a 2 in the second regions 11c1 and 11c 2. Further, the second region 11c1 has the raised region 11b1 on the central-axis side thereof where the central axis of the first opening 11a1 is located. The raised region 11b1 surrounds the first opening 11a1 and rises upward relative to the upper surface of the first region 11c, as illustrated in FIG. 7. Similarly, the second region 11c2 has the raised region 11b2 on the central-axis side thereof where the central axis of the first opening 11a2 is located. The raised region 11b2 surrounds the first opening 11a2 and rises upward relative to the upper surface of the first region 11c.

Further, as described in the second embodiment, the case 11 may include the annular first portion 11e1 that is located on the central-axis side of the raised region 11b1 where the central axis of the first opening 11a1 is located. The first portion 11e1 surrounds the first opening 11a1 and is parallel to the upper surface of the case 11 (see FIGS. 12A and 12B). In this connection, the first portion 11e1 may be formed as an arch-shaped portion having an upwardly convex curvature relative to the upper surface of the case 11 in a sectional view.

Still further, as described in the third embodiment, the second region 11c1 may be connected to the first region 11c via the connection region 11c1a whose thickness decreases from both the front and back surfaces toward the central axis of the first opening 11a1 (see FIGS. 14A and 14B).

Still further, as described in the fourth embodiment, the case 11 may has, in the second region 11c1, the annular recess 11d1 provided to surround the first opening 11a1, at a position farther from the first opening 11a1 than the position of the raised region 11b1. The case 11 may also have, in the second region 11c1, the groove 11f1 at a position farther from the first opening 11a1 than the position of the recess 11d1 (see FIGS. 16A and 16B).

In addition, the case 11 has the terminals 12a to 12c that each have one end protruding into the case from the inner surface of the case and the other end exposed to the outside of the case 11. The terminals 12a to 12c are formed integrally with the case 11.

The components having the second openings, which are prepared in step P1, include the insulated circuit substrate 20 and the printed board 30. As illustrated in FIG. 3B, FIG. 7, and others, the insulated circuit substrate 20 includes the conductive pattern layers 20a1 to 20a3, the metal layer 20b, and the insulating layer 20c sandwiched between the conductive pattern layers 20a1 to 20a3 and the metal layer 20b. The conductive pattern layers 20a 1 and 20a2 have third openings 20d1 and 20d2, as the second openings of the components, at the same positions as the first openings 11a1 and 11a2 in plan view.

As illustrated in FIG. 3A, FIG. 7, and others, the printed board 30 has the conductive pattern layers 30a1 to 30a3, the conductive pattern layer 30b, and the insulating layer 30c provided between the conductive pattern layers 30a 1 to 30a3 and the conductive pattern layer 30b. The printed board 30 has the second openings 30d1 and 30d2, as the second openings of the components, at the same positions as the first openings 11a1 and 11a 2 in plan view.

[Step P2] A step of mounting the semiconductor elements 13a to 13h on the insulated circuit substrate 20 is performed. In step P2, the semiconductor elements 13a to 13h and the pin-shaped connection members 14a and 14b are mounted on the conductive pattern layers 30a 1 to 30a3 via the bonding members in a state where the insulated circuit substrate 20 is set in a jig used for bonding. Further, bonding members are provided on the semiconductor elements 13a to 13h and the pin-shaped connection members 14a and 14b for bonding to the printed board 30. Step P2 does not involve the bonding operation.

[Step P 3] The positioning members are inserted into the third openings 20d 1 and 20d2 of the insulated circuit substrate 20.

[Step P 4] The printed board 30 is mounted over the insulated circuit substrate 20 such that the positioning members are inserted into the second openings 30d1 and 30d2.

[Step P 5] The case 11 is set such that the positioning members are inserted into the first openings 11a1 and 11a 2.

As described above, the case 11 and the components (the insulated circuit substrate 20 and the printed board 30) to be provided inside the case 11 are positioned as follows.

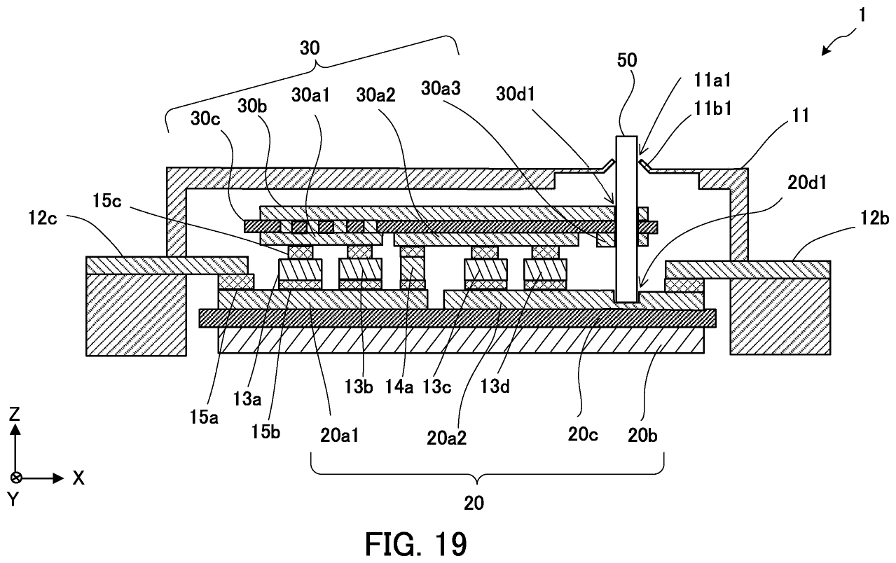

FIG. 19 is a sectional view illustrating a state of the positioning using the positioning members. FIG. 19 illustrates an example in which the positioning is performed in the semiconductor module 1 of the first embodiment.

A pin-shaped positioning member 50 that is common to the first opening 11a1, the second opening 30d 1, and the third opening 20d1 is fixed in a state where the third opening 20d 1 passes through the first opening 11a1 and the second opening 30d1 and abuts against the bottom portion of the third opening 20d1 of the insulated circuit substrate 20. Bonding is performed in this state.

[Step P 6] A bonding step is performed. In the bonding step, the terminals 12a to 12c of the case 11 are bonded onto the insulated circuit substrate 20. The semiconductor elements 13a to 13h and the pin-shaped connection members 14a and 14b are bonded to the conductive pattern layers 20a1 to 20a3 of the insulated circuit substrate 20. Further, the semiconductor elements 13a to 13h and the connection members 14a and 14b are bonded to the printed board 30. In the case where solder is used as the bonding member, the bonding step is performed under predetermined reflow conditions. In the case where a sintered material (copper or silver) is used as the bonding member, the bonding step is performed under predetermined sintering conditions.

[Step P 7] The positioning members are removed.

[Step P 8] A sealing step using transfer molding is performed. The sealing step using transfer molding is performed as illustrated in FIGS. 8A, 8B and 9 described above.

For example, in manufacturing the semiconductor module 1 of the first embodiment, as illustrated in FIG. 9, the upper end 11e of the raised region 11b1 and the main surface of the upper mold 60a are brought into contact with each other by pressing with the upper mold 60a, thereby closing the gap between the upper surface of the case 11 and the main surface of the upper mold 60a. This inhibits the sealing resin 40 from leaking out of the case 11 through the first opening 11a1. Thus, a molding defect caused by such leakage of the sealing resin 40 out of the case 11 is prevented. In addition, by pressing with the upper mold 60a in the first opening 11a1, the recess that annularly surrounds the first opening 11a1 is formed in the second region 11c1. Therefore, even if the sealing resin 40 leaks out of the case 11 beyond the upper end 11e, the sealing resin 40 flows into the recess. This inhibits the sealing resin 40 from leaking and spreading to the outside of the recess in plan view.

After the sealing resin 40 filling the case 11 is cured, the molds (the upper mold 60a and the lower mold 60b in FIG. 9) are removed, thereby obtaining the semiconductor module 1 illustrated in FIG. 10. The semiconductor modules of the second to fourth embodiments are also manufactured in accordance with the same steps as described above.

The above-described example uses the bonding members, such as solder, for bonding. Alternatively, ultrasonic bonding may be used for the bonding.

### Modification

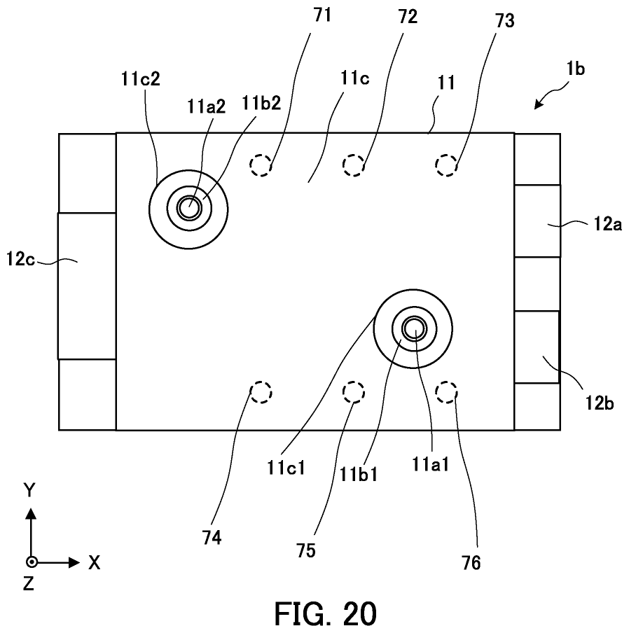

FIG. 20 illustrates a modification of a semiconductor module. In FIG. 20, the same elements as those illustrated in FIG. 6 are denoted by the same reference numerals.

A case 11 in a semiconductor module 1b of the modification has support members 71 to 76 extending from the upper surface in the −Z direction. For example, the support members 71 to 76 may be formed integrally on the upper surface of the case 11 when the case 11 is molded. As described above, when this case 11 is attached to the insulated circuit substrate 20 using the positioning members, although not illustrated, the −Z-side tips of the support members 71 to 76 are brought into contact with the front surface of the insulated circuit substrate 20. The use of these support members 71 to 76 makes it possible to suppress the warping of the upper surface of the case 11. Therefore, as described above, when the upper surface of the case 11 is pressed by the upper mold 60a in the sealing step, the upper surface of the case 11 is reliably supported from the inside by the support members 71 to 76, and the gap between the upper surface of the case 11 and the upper mold 60a is more reliably eliminated.

Heretofore, one aspect of the semiconductor module and the manufacturing method for the same according to the embodiments has been described above with reference to the embodiments. However, these are merely examples, and the present disclosure is not limited to the above description.

According to the disclosed techniques, it becomes possible to prevent a molding defect caused by leakage of a sealing resin out of a case during transfer molding.

The following supplementary notes are additionally provided in connection with the embodiments including the first to fourth embodiments.

(Supplementary Note 1) A semiconductor module, comprising:
a case including a first region and a second region on an upper surface thereof, the second region being thinner than the first region and including a first opening and a recess annularly surrounding the first opening; and
a sealing resin filling the case.

(Supplementary Note 2) The semiconductor module according to supplementary note 1, wherein the case has an upper end that is level with an upper surface of the first region, at a position closer to the first opening than a position of the recess in a plan view of the semiconductor module.

(Supplementary Note 3) The semiconductor module according to supplementary note 1, wherein the case includes, in the second region, an annular raised region rising from the recess toward a central axis of the first opening.

(Supplementary Note 4) The semiconductor module according to supplementary note 3, wherein the case includes an annular first portion that is located on a central-axis side of the raised region where the central axis of the first opening is located, the first portion surrounding the first opening and being inclined downward toward the central axis of the first opening.

(Supplementary Note 5) The semiconductor module according to supplementary note 1, wherein
the second region includes a connection region that is continuous with the first region,
the connection region has an upper surface that descends from a same height as an upper surface of the first region to a height lower than the upper surface of the first region, toward the central axis of the first opening, and
the connection region has a thickness that decreases toward the central axis.

(Supplementary Note 6) The semiconductor module according to supplementary note 1, wherein the case includes a groove in the upper surface thereof at a position farther from the first opening than a position of the recess.

(Supplementary Note 7) The semiconductor module according to supplementary note 1, wherein the sealing resin fills up to an upper surface of an inner wall of the case, and has a sealing surface in the first opening, the sealing surface being level with an upper surface of an outer wall of the case.

(Supplementary Note 8) The semiconductor module according to supplementary note 1, further comprising a semiconductor element and a conductive pattern layer on which the semiconductor element is disposed, upper surfaces of the semiconductor element and the conductive pattern layer being at least partly covered by the case,
wherein the semiconductor element is provided in a region other than a region directly below the first opening.

(Supplementary Note 9) The semiconductor module according to supplementary note 1, further comprising:
a semiconductor element, a plurality of conductive pattern layers, and a connection member that either electrically connects one of the plurality of conductive pattern layers to the semiconductor element or electrically connects the plurality of conductive pattern layers,
wherein the connection member is provided in a region other than a region directly below the first opening, or the connection member includes a second opening at a same position as the first opening in a plan view of the semiconductor module.

(Supplementary Note 10) The semiconductor module according to supplementary note 1, wherein the case includes a terminal having one end protruding into the case from an inner surface of the case and another end exposed to an outside of the case.

(Supplementary Note 11) The semiconductor module according to supplementary note 9, wherein a part of the connection member is a printed board.

(Supplementary Note 12) The semiconductor module according to supplementary note 1, further comprising:
a semiconductor element; and
an insulated circuit substrate to which the semiconductor element is bonded, the insulated circuit substrate being disposed inside the case and being sealed together with the semiconductor element by the sealing resin inside the case,
wherein the insulated circuit substrate includes an insulating layer and a conductive pattern layer to which the semiconductor element is bonded.

(Supplementary Note 13) The semiconductor module according to supplementary note 12, wherein the conductive pattern layer of the insulated circuit substrate includes a third opening at a same position as the first opening in a plan view of the semiconductor module.

(Supplementary Note 14) The semiconductor module according to supplementary note 13, wherein the third opening does not penetrate through the conductive pattern layer.

(Supplementary Note 15) The semiconductor module according to supplementary note 1, wherein the sealing resin is a rigid resin.

(Supplementary Note 16) A manufacturing method for a semiconductor module, comprising:
preparing a case including, on an upper surface thereof, a first region and a second region having a first opening, and a component including a second opening, the second region being thinner than the first region and including a raised region on a central-axis side thereof where a central axis of the first opening is located, the raised region surrounding the first opening and rising upward relative to an upper surface of the first region; and
injecting a sealing resin into the case in a state where the first opening and the second opening are positioned, and the upper surface of the case accommodating the component is pressed by a main surface of a mold facing the upper surface of the case so that the raised region is pushed downward.

(Supplementary Note 17) The manufacturing method for the semiconductor module according to supplementary note 16, wherein the injecting of the sealing resin is performed in a state where an upper end of the raised region and the main surface of the mold are in contact with each other by pressing with the mold.

(Supplementary Note 18) The manufacturing method for the semiconductor module according to supplementary note 16, wherein
the case prepared includes an annular first portion that is located on the central-axis side of the raised region, the first portion surrounding the first opening and being parallel to the upper surface of the case, and
the injecting of the sealing resin includes injecting the sealing resin in a state where the mold presses the first portion to push the first portion and the raised region downward from the upper surface of the case.

(Supplementary Note 19) The manufacturing method for the semiconductor module according to supplementary note 16, wherein
the second region includes a connection region that is continuous with the first region,
the connection region has an upper surface that descends from a same height as the upper surface of the first region to a height lower than the upper surface of the first region, toward the central axis, and
the connection region has a thickness that decreases toward the central axis.

(Supplementary Note 20) The manufacturing method for the semiconductor module according to supplementary note 16, wherein the case includes, in the second region, an annular recess provided to surround the first opening, at a position farther from the first opening than a position of the raised region, and a groove provided at a position farther from the first opening than the position of the recess.

(Supplementary Note 21) The manufacturing method for the semiconductor module according to supplementary note 16, wherein the first opening and the second opening are positioned by inserting a common positioning member into the first opening and the second opening.

(Supplementary Note 22) The manufacturing method for the semiconductor module according to supplementary note 16, wherein the sealing resin is a rigid resin.

(Supplementary Note 23) A semiconductor module, comprising:
a case including a first opening in an upper surface thereof;
a printed board disposed inside the case and including a second opening at a same position as the first opening in a plan view of the semiconductor module; and
an insulated circuit substrate disposed below the printed board inside the case, the insulated circuit substrate including an insulating layer and a conductive pattern layer to which a semiconductor element is bonded, the conductive pattern layer including a third opening at a same position as the first opening and the second opening in the plan view.

(Supplementary Note 24) A manufacturing method for a semiconductor module, comprising:
preparing a case including a first opening in an upper surface thereof, a printed board including a second opening, and an insulated circuit substrate including an insulating layer, a conductive pattern layer to which a semiconductor element is bonded, and a third opening formed in the conductive pattern layer;
performing bonding in a state where the case, the printed board accommodated inside the case, and the insulated circuit substrate disposed below the printed board are positioned by inserting a common positioning member into the first opening, the second opening, and the third opening; and
injecting, after removing the positioning member, a sealing resin into the case to seal the printed board and the insulated circuit substrate.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor module, comprising:
a case including a first region and a second region on an upper surface thereof, the second region being thinner than the first region and having a first opening and a recess, which annularly surrounds the first opening in a plan view of the semiconductor module, formed therein; and
a sealing resin filling the case.

2. The semiconductor module according to claim 1, wherein the case has an upper end that is level with an upper surface of the first region, and is closer to the first opening than is the recess in the plan view of the semiconductor module.

3. The semiconductor module according to claim 1, wherein the case further has an annular raised region, which rises from the recess toward a central axis of the first opening, formed in the second region.

4. The semiconductor module according to claim 3, wherein the case further includes an annular first portion that is located closer to the central axis of the first opening than is the annular raised region in the plan view, the first portion surrounding the first opening and being inclined downward toward the central axis of the first opening.

5. The semiconductor module according to claim 1, wherein
the case further has, in the second region, a connection region that is continuous with the first region,
the connection region has an upper surface that descends from a height of an upper surface of the first region as the connection region extends toward a central axis of the first opening, and
the connection region has a thickness that decreases as the connection region extends toward the central axis.

6. The semiconductor module according to claim 1, wherein the case includes a groove in the upper surface thereof, the groove being farther from the first opening than is the recess in the plan view of the semiconductor module.

7. The semiconductor module according to claim 1, wherein the sealing resin fills up to an upper surface of an inner wall of the case, and has a sealing surface in the first opening, the sealing surface being level with an upper surface of an outer wall of the case.

8. The semiconductor module according to claim 1, further comprising:
a semiconductor element, and
a conductive pattern layer on which the semiconductor element is disposed, upper surfaces of the semiconductor element and the conductive pattern layer being at least partly covered by the case, wherein
the semiconductor element is provided in a region other than a region directly below the first opening.

9. The semiconductor module according to claim 1, further comprising:
a semiconductor element;
a plurality of conductive pattern layers; and
a connection member that either electrically connects one of the plurality of conductive pattern layers to the semiconductor element or electrically connects the plurality of conductive pattern layers,
wherein the connection member is either provided in a region other than a region directly below the first opening, or has a second opening at a same position as the first opening in the plan view of the semiconductor module.

10. The semiconductor module according to claim 9, wherein a part of the connection member is a printed board.

11. The semiconductor module according to claim 1, wherein the case includes a terminal having one end protruding into the case from an inner surface of the case and another end exposed to an outside of the case.

12. The semiconductor module according to claim 1, further comprising:
a semiconductor element; and
an insulated circuit substrate to which the semiconductor element is bonded, the insulated circuit substrate being disposed inside the case and being sealed together with the semiconductor element by the sealing resin inside the case,
wherein the insulated circuit substrate includes an insulating layer and a conductive pattern layer to which the semiconductor element is bonded.

13. The semiconductor module according to claim 12, wherein the conductive pattern layer of the insulated circuit substrate includes a third opening at a same position as the first opening in the plan view of the semiconductor module.

14. The semiconductor module according to claim 13, wherein the third opening does not penetrate through the conductive pattern layer.

15. The semiconductor module according to claim 1, wherein the sealing resin is a rigid resin.

16. A manufacturing method for a semiconductor module, comprising:
preparing
a case including, on an upper surface thereof, a first region and a second region having a first opening, the second region being thinner than the first region, and including a raised region that is closer to a central axis of the first opening than is a remaining portion of the second region, the raised region surrounding the first opening and rising upward relative to an upper surface of the first region, and
a component having a second opening formed therein; and
injecting a sealing resin into the case while
the component is placed in the case with the first opening and the second opening aligned, and
the upper surface of the case accommodating the component is pressed by a main surface of a mold facing the upper surface of the case so that the raised region is pushed downward.

17. The manufacturing method for the semiconductor module according to claim 16, wherein the injecting of the sealing resin is performed while an upper end of the raised region and the main surface of the mold are in contact with each other by pressing with the mold.

18. The manufacturing method for the semiconductor module according to claim 16, wherein
the case prepared further includes an annular first portion that is located closer to the central axis of the first opening than is the raised region, the first portion surrounding the first opening and being parallel to the upper surface of the case, and
the injecting of the sealing resin includes injecting the sealing resin while the mold presses the first portion to thereby push the first portion and the raised region downward from the upper surface of the case.

19. The manufacturing method for the semiconductor module according to claim 16, wherein
the second region includes a connection region that is continuous with the first region,
the connection region has an upper surface that descends from a height of the upper surface of the first region as the connection region extends toward the central axis, and
the connection region has a thickness that decreases as the connection region extends toward the central axis of the first opening.

20. The manufacturing method for the semiconductor module according to claim 16, wherein the case further has, in the second region,
an annular recess provided to surround the first opening, and being farther from the first opening than is the raised region, and
a groove that is farther from the first opening than is the recess.

21. The manufacturing method for the semiconductor module according to claim 16, wherein the first opening and the second opening are positioned by inserting a common positioning member into the first opening and the second opening.

22. The manufacturing method for the semiconductor module according to claim 16, wherein the sealing resin is a rigid resin.

23. A manufacturing method for a semiconductor module, comprising:
preparing
a case including a first opening in an upper surface thereof,
a printed board including a second opening,
an insulated circuit substrate including
an insulating layer, and
a conductive pattern layer having a third opening formed therein, and
a semiconductor element bonded to the conductive pattern layer;
performing bonding while the case, the printed board accommodated inside the case, and the insulated circuit substrate disposed below the printed board are positioned by inserting a common positioning member into the first opening, the second opening, and the third opening; and
injecting, after removing the positioning member, a sealing resin into the case to seal the printed board and the insulated circuit substrate.
